(19) United States
(12) Patent Application Publication
(10) Pub. No.: US 2005/0091392 A1
(43) Pub. Date: Apr. 28, 2005

(54) Method and device for codec negotiation

(76) Inventors: Lothar Gesswein, Germering (DE); Rudiger Kreuter, Munchen (DE); Rita Leirich, Munchen (DE); Bernd Siegwart, Ettringen (DE)

Correspondence Address: Siemens Corporation;Intellectual Property Department, 170 Wood Avenue South, Iselin, NJ, 08830, US

(21) Appl. No.: 10/499,743

(22) PCT Filed: Dec. 12, 2002
(86) PCT No.: PCT/DE02/04561

(30) Foreign Application Priority Data
Dec. 21, 2001 (DE) 101 63 478.1

(51) Int. Cl. G06F 15/16; H03M 7/00

(52) U.S. Cl. 709/231; 709/249; 709/230; 341/89

(57) ABSTRACT

A method for codec negotiation between two gateway controllers, wherein the gateway controllers manage, in a link-independent manner, a codec list with codec types which are supported by the respective media gateway, thereby avoiding ultimate disconnection of a set-up link as a result of unsupported codecs.

### CROSS REFERENCE TO RELATED APPLICATIONS

This application is the US National Stage of International Application No. PCT/DE02/04561, filed Dec. 12, 2002 and claims the benefit thereof. The International Application claims the benefits of German application No. 10163478.1 filed Dec. 21, 2001, both of the applications are incorporated by reference herein in their entirety.

### FIELD OF INVENTION

The invention relates to a method for codec negotiation for a data transmission between two media gateways and to a device related hereto.

### BACKGROUND OF INVENTION

As a result of historical developments, there are two communications infrastructures within most businesses. First there is the infrastructure for data communication (LAN), and secondly there is the network of private branch exchanges with the telecommunications unit in central position.

Having separate systems is uneconomical, however, since each of these two communications systems requires its own network technology. As a result of this, it is necessary to maintain twice as much know-how to operate and maintain the systems. Furthermore, having separate systems like this stands in the way of the rapid development of new applications since the two systems are based on different technologies. Whilst the traditional telephone network establishes in each phone call an end-to-end connection having a reserved bandwidth of 64 Kbps, in IP telephony, speech is digitized, compressed, converted into IP data packets and routed across the data networks together with other IP traffic.

There is therefore a desire to bring together the two separate “worlds” with the aim of increasing the effectiveness and productivity of modern businesses, thus giving them a decisive competitive advantage.

In order to be able to handle real time-oriented speech applications via the packet-oriented IP protocol, it is necessary to compress the data that have to be transmitted. For this reason, the ITU (International Telecommunications Union) has adopted a number of standards which provide different speech qualities irrespective of the bandwidth that can be used. These compression methods are also known as codecs and are hardware and/or software modules which combine within themselves the functions of a coder and a decoder since, when information is transmitted between two points, the transmission frequently goes in two directions. Sometimes the codec is specially customized for characteristics (bandwidth, packetization period, ring tone characteristics) of an input signal, for example speech and/or video signals. Practical implementation is achieved either as hardware by DSPs (Digital Signal Processors) or by software-implemented codec algorithms.

In order to minimize the storage space required for a complex data stream, for example audio and/or video data, the data are also regularly compressed according to defined algorithms. To use the data, a decompression algorithm is required, which reverses the compression after transmission or storage. This means that each compression involves a respective decompression which inverts precisely this compression. The hardware and software solutions created for the above purpose are also generally known as codecs. A data stream coded or compressed with a specific codec can be decompressed only by this codec.

H.323 denotes a standard for audio-, video-,and data-communication via an IP-based network. The H.323 set of protocols comprises the following codec standards for example: G. 711, G. 722, G. 723, G. 728 and G. 729, with the G.711 standard offering uncompressed transmission, as is also used in music CD technology and in the ISDN network. The above standard is strictly prescribed for all H.323 systems and in principle (discounting potential packet delays) it offers the best quality by virtue of the minimal delay. The above method has a data rate of 56 Kbps or 64 Kbps and a bandwidth of 3.1 kHz. If more powerful signal processors are used for coding, then the bit rates required can be compressed to 5.3 Kbps, whilst maintaining a very good speech quality. This does result in longer delays, however.

Low bandwidth requirements are desirable at the subscriber end, firstly for reasons of local connection technology, for example in modem lines, and secondly to avoid jams in the network. This is because the greater the bandwidth required, the more likely (in a given maximum bandwidth of the transmission path) is the probability of delayed packet deliveries or even the loss of packets.

All the types of codec referred to above have certain advantages: G.723 has the lowest bandwidth but a very high delay. G. 728 has a low delay but still has a data rate of 16 Kbps. G.729 has an average delay and a data rate of 8 Kbps.

Further codecs are for instance MP3 (MPEG Layer III Audio) for high quality transmission of audio data on the Internet, H. 261 and H. 263 for videoconferencing with low or average quality or Sorensen Video for high quality video data transmission over IP networks.

With the above codecs, the data are coded to reduce the storage space required or to accelerate data transmission. At the receiving end, the codec used to transmit the data must be available for decoding/decompressing the data received, as already mentioned above. Therefore, when establishing a voice link via an IP network (VoIP) an appropriate codec has to be set both at the transmitting end and at the receiving end of the link. The media gateways at both ends of the IP network are controlled by appropriate media gateway controllers (MGCs).

In a VoIP link set-up, the above MGCs negotiate about the codec that is to be used. As the basis of negotiations, both MGCs each use an administratively pre-established codec list. If a codec not supported by both media gateways is then selected from this codec list the link is disconnected.

### SUMMARY OF INVENTION

The present invention therefore addresses the problem of providing an improved method of codec negotiation which is both faster and successful even in heterogeneous networks. Furthermore it aims to provide an appropriate device to carry out the method.

With respect to the method, the above problem is solved by providing a method that forms the subject matter of claim 1. With respect to the device, the solution to the above problem is shown in claim 7.

An essential idea underlying the invention is that the media gateway controllers not only carry out a negotiation for a link set-up using the administratively pre-established codec list, but also have recourse to a further codec list that they manage themselves, each of which lists contains the codecs actively supported by the assigned media gateway. Recourse to both codec lists, both the administratively pre-established list and the active codec list is achieved such that only codecs included in both lists are used for negotiation. Only codecs from the intersection of both codec lists are available so to speak. Subsequent disconnection of the link due to unsupported codecs is thus avoided. The process of negotiation is accelerated because codec negotiation is now carried out only by the gateway controllers. The gateways themselves are merely informed as to which codec has been negotiated.

In an advantageous embodiment of the present invention, the controller of the receiving gateway (second gateway controller) establishes a list of the codecs that are included both in the codec list transmitted by the controller of the transmitting gateway (first gateway controller) and in the active codec list from the second gateway controller. The above list is further transmitted to the first gateway controller. Both controllers store the above list for the duration of the link. As a result, both gateway controllers have at their disposal a list of codecs that are supported by both media gateways participating in the above link.

In a further advantageous embodiment of the present invention, the active codec list contains only codecs that are both currently supported by each gateway and included in each administratively pre-established codec list. This leads to a further increase in negotiation performance. The above active list may therefore contain a lower number of codecs because the media gateway also supports codecs that are not included in the administratively pre-established codec list.

In a further advantageous embodiment, the management of the active codec list is carried out in such a way that when a gateway in the network first calls up, the assigned gateway controller is notified of the codecs supported by the gateway. As a result of the above notification, the gateway controller is able to establish the active codec list. Furthermore, the gateway controller is notified of changes regarding the codecs that are supported so that the active codec list contains the respective current status of the codecs that can be used.

In a further preferred embodiment, the gateway controller periodically interrogates the gateway assigned thereto in order to maintain the active codec list at current status in each case. Changes regarding the codecs supported by the gateway are entered in the active codec list in the next interrogation.

In a further advantageous embodiment, there is a switch-over to another codec during a link. The above codec is included in the codec list transmitted by the second gateway controller to the first gateway controller. Consequently the above codec is supported by both two media gateways and, during a link or a data transmission, a switch-over can be made in each case to a codec having the current most favorable transmission parameters.

The administratively pre-established codec list preferably contains at least the codecs referred to in the H. 323 standard. Consequently the administratively pre-established codec list shows the codecs relevant to most VoIP links.

Advantageous aspects of the device according to the invention come to light in accordance with the above description of the advantageous aspects of the method according to the invention.

A preferred embodiment of the device according to the invention additionally has a further memory device on each side of the link, in which device the codec lists are stored for the duration of a link, and which device contains the codes that are included in the two active codec lists and in the administratively pre-established codec lists. The above stored list includes so to speak the intersection of all relevant codec lists, and a codec selected from said intersection is supported by both ends of the link.

In a further advantageous embodiment of the device according to the invention, in each of the gateway controllers a single physical memory is provided, in which the various codec lists are stored. This simplifies the set-up of the device since only one memory unit is required.

### BRIEF DESCRIPTION OF THE DRAWINGS

Advantages and uses of the invention also emerge from the sub-claims and from the following description of a preferred embodiment with the aid of the figures. The figures show:

FIG. 1: a device for a conventional codec negotiation and

FIG. 2 a device for a codec negotiation according to the present invention.

### DETAILED DESCRIPTION OF INVENTION

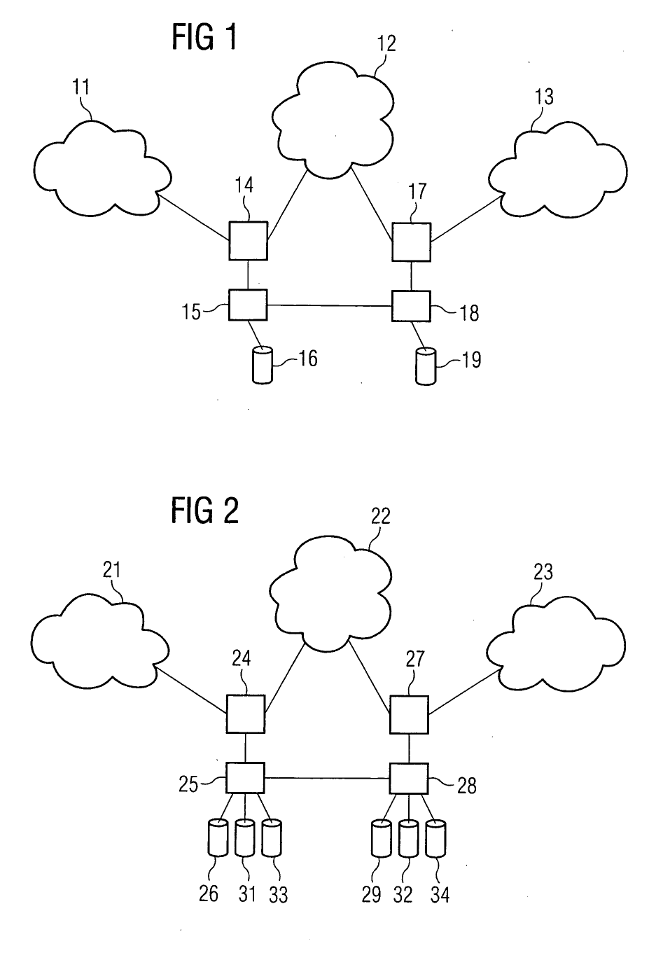

FIG. 1 represents a device for a conventional codec negotiation and shows a transmission network 11, a link network 12 and also a receiving network 13. The transmission network 11 and the link network 12 are connected via a media gateway 14. The media gateway 14 is controlled by a gateway controller 15 assigned thereto. The controller 15 accesses a database 16, in which an administratively pre-established codec list is stored.

The link network 12 is linked with the receiving network 13 via a further media gateway 17. The media gateway 17 is controlled by a gateway controller 18, which itself accesses a database 19. The database 19 stores an administratively pre-established codec list, which may differ from the codec list stored in the database 16. The gateway controllers 15, 18 are connected to each other in order to carry out the codec negotiation with each other.

The function or course of a codec negotiation is now explained below with the aid of the figure. When setting up a voice link between the transmission network 11 and the receiving network 13, the two gateway controllers 15, 18 negotiate about the codec that is to be used. In such a process, the gateway controller 15 selects its preferred or prioritized codec type from the codec list stored in the database 16. It first signals the above codec type using a Create Connection Request

(CRCX) to the gateway 14 which only then sets the above codec as the codec type to be used for the link. Furthermore, the controller 15 notifies the controller 18 of the complete codec list from the database 16.

From the codec list that it has received, the controller 18 now selects a codec type by comparing the codec list received with the codec list that has been stored in the database 19. When it does this it selects, from the codec list that it has received, the codec that has the highest priority in its administratively pre-established codec list. It notifies the gateway 17 of the above codec type in a Create Connection Request (CRCX).

If this codec type is accepted by the gateway 17, the controller 18 notifies the gateway controller 15. If the gateway 17 does not accept the codec type selected by the controller 18, then the controller 18 selects a further codec type and notifies the gateway 17 of the newly selected type. This continues until a codec type has been accepted by the gateway 17. If it fails to find a common codec type, the link is disconnected by the receiving end. If a codec type that is not accepted or supported by the gateway 14 is selected by the receiving end and notified to the transmitting end, then in this case the link is disconnected by the transmitting end.

In a homogeneous network in which all the gateways are of one type, it can be guaranteed by correct administration of the codec lists that the same codec types are used at the transmitting and receiving end. However, in a heterogeneous network that uses gateways from different manufacturers this is not guaranteed.

Furthermore when, during a voice link, there is a switch-over to a fax/modem transmission, the page that recognizes the fax/modem tone will initiate the switch-over to the fax-specific codec type and in the process also give notification relating to the above selected codec type. If on the other hand, the above codec is not supported, the link is disconnected.

FIG. 2 shows a device for a codec negotiation according to the invention, which device is essentially similar to the device shown in FIG. 1. As an addition to the device as per FIG. 1, the device shown in FIG. 2 has further databases 31 and 33, which the gateway controller 25 accesses. Likewise, the gateway controller 28 accesses further databases 32 and 34. Databases 31, 32 store additional codec lists known as the active codec lists (codec cache). Here the active codec list in the database 31 contains the codecs that are supported by the gateway 24, and the database 32 contains the codecs that are supported by the gateway 27. The databases 33 and 34 contain further codec lists, which are identical. This codec list contains only the codecs that are included in the administratively pre-established codec list from the databases 26 and 29.

The codec negotiation method according to the invention is explained below. In the method according to the invention, independent of a call set-up in the background, codec types are interrogated periodically by the gateway controller 25 at the gateway 24. The codec types that are supported by the gateway 24 are stored in the database 31 as an active code list. In the same way, the gateway controller 28 periodically interrogates the codec types at the gateway 27 in order to store the accepted codec types as an active codec list in the database 32. Alternatively or additionally the active codec list can be established such that, when the gateway 24 or 27 first calls the network, all the respective codecs that are supported are notified to the gateway controller 25 or 28. Changes in the codecs that are supported are also notified to the gateway controller 25 or 28. Knowledge relating to the codec types that are supported is therefore built up and stored individually for each gateway, independent of a call set-up.

When setting up a link, the gateway controllers 25 and 28 engage in a codec negotiation. The list that the gateway controller 25 transmits to the gateway controller 28 is not the codec list from the database 26, but a codec list that contains only codec types that are included in both the codec list from the database 31 and in the codec list from the database 26. The gateway controller 28 therefore receives a codec list containing codec types that are always supported by the gateway 24. This avoids any subsequent disconnection of the link because a codec type is not accepted by the gateway 24. From the codec list that it has received the gateway controller 28 now selects a codec type that is likewise included in the codec list of the database 32 and in the codec list of the database 29. Since the codec type selected is also included in the active codec list from the database 32, it is supported by the gateway 27. Both the gateway controllers 25, 28 can therefore negotiate in the codec negotiation only with respect to codec types that are supported by the gateways 24 and 27. This excludes the possibility of any subsequent disconnection because a codec type is not accepted by one of said two gateways 24, 27.

In addition to the codec types that have to be signaled in the codec negotiation for a voice link, all the available codec types are transmitted in each case from the transmitting end to the receiving end and likewise from the receiving end to the transmitting end. The above codec list includes so to speak the intersections of the codec lists from the databases 26, 29, 31 and 32. The codec types included therein are supported by both gateways 24 and 27. Both the gateway controllers 25 and 28 store this codec list in the databases 33 and 34.

If, during a link, a switch-over is now made to a fax/modem transmission, then each codec type can be selected by each end from the intersection codec list in the databases 33, 34. This then guarantees that in all cases, the call can be successfully switched over and that there is no disconnection.

The implementation of the invention is not restricted to the examples that have been described and the aspects highlighted above, but is also possible within the scope of the claims in a plurality of variants that fall within the scope of normal trade practice.

1-10. (canceled)

11. A method for codec negotiation for a data transmission between two media gateways, comprising:
linking the media gateways via a network;
controlling the media gateways by a control unit;
setting up a link between a first control unit, which is assigned to the transmitting gateway, and a second control unit, which is assigned to the receiving gateway;
transmitting a codec list to the second control unit by the first control unit, wherein the codec list is predetermined in the first control unit;
selecting a codec from the transmitted codec list;
transmitting the selected codec to the receiving gateway by the second control unit;
transmitting the selected codec from the second control unit to the first control unit;
transmitting the transmitted codec from the first control unit to the transmitting gateway;
transmitting the data from the transmitting gateway to the receiving gateway using the transmitted codec, wherein
the control units each manage an active codec list of codecs that are supported by each assigned gateway, wherein
the codec list has, during the transmitting a codec list step, only codecs that are supported by the transmitting gateway, and wherein
during the selecting a codec from the transmitted codec list step, a codec is selected that is in the active codec list managed by the second control unit.

12. A method according to claim 11, wherein the codec list is administratively predetermined in the first control unit.

13. A method according to claim 11, wherein the second control unit establishes a list of codecs that are included in the codec list transmitted by the first control unit and in the active codec list of the second control unit, and transmits the established list to the first control unit, and wherein the control units store the established list for the duration of a link.

14. A method according to claim 11, wherein the active codec lists comprise only codecs that are supported both by each gateway and are included in each predetermined codec list.

15. A method according to claim 13, wherein the active codec lists comprise only codecs that are supported both by each gateway and are included in each predetermined codec list.

16. A method according to claim 1 1, wherein when a gateway first calls the network and/or when changes are made, the gateway notifies the respective control unit of the codecs that it supports.

17. A method according to claim 13, wherein when a gateway first calls the network and/or when changes are made, the gateway notifies the respective control unit of the codecs that it supports.

18. A method according to claim 11, wherein the control unit periodically interrogates the respective gateway assigned thereto regarding the codecs that are supported by the gateway.

19. A method according to claim 13, wherein the control unit periodically interrogates the respective gateway assigned thereto regarding the codecs that are supported by the gateway.

20. A method according to claim 13, wherein during a link, a switch-over is made to another codec that is included in the codec list transmitted by the second control unit to the first control unit.

21. A device for performing a method for codec negotiation for a data transmission between two media gateways, the device comprising:
a transmitting gateway;
a receiving gateway;
a first control unit assigned to the transmitting gateway and having a first memory unit for storing a codec list;
a second control unit assigned to the reception gateway and having a second memory unit for storing a codec list, wherein
the first and the second control unit each have third memory units for storing an active codec list showing the codecs that are supported by each gateway assigned thereto, wherein the method comprising:
linking the media gateways via a network;
controlling the media gateways by a control unit;
setting up a link between a first control unit, which is assigned to the transmitting gateway, and a second control unit, which is assigned to the receiving gateway;
transmitting a codec list to the second control unit by the first control unit, wherein the codec list is predetermined in the first control unit;
selecting a codec from the transmitted codec list;
transmitting the selected codec to the receiving gateway by the second control unit;
transmitting the selected codec from the second control unit to the first control unit;
transmitting the transmitted codec from the first control unit to the transmitting gateway;
transmitting the data from the transmitting gateway to the receiving gateway using the transmitted codec, wherein
the control units each manage an active codec list of codecs that are supported by each assigned gateway, wherein
the codec list has, during the transmitting a codec list step, only codecs that are supported by the transmitting gateway, and wherein
during the selecting a codec from the transmitted codec list step, a codec is selected that is in the active codec list managed by the second control unit.

22. A device according to claim 21, wherein the first and the second control unit have a fourth memory unit for storing a codec list showing the codecs that, during a link, are included in both active codec lists and in both the codec lists from each of the first memory units.

23. A device according to claim 21, wherein in the first control unit a physical memory is provided for each of the memory units.

24. A device according to claim 21, wherein in the second control unit a physical memory is provided for each of the memory units.

25. A device for codec negotiation for a data transmission between two media gateways, comprising:
a transmitting gateway;
a receiving gateway;
a first control unit assigned to the transmitting gateway and having a first memory unit for storing a codec list;
a second control unit assigned to the reception gateway and having a second memory unit for storing a codec list, wherein
the first and the second control units comprise a third memory unit for storing an active codec list showing the codecs that are supported by each gateway assigned thereto.

26. A device according to claim 25, wherein the first and the second control unit each have a fourth memory unit for storing a codec list showing the codecs that, during a link, are included in both active codec lists and in both the codec lists from each of the first memory units.
